(19) United States
(12) Patent Application Publication
(10) Pub. No.: US 2006/0172511 A1
(43) Pub. Date: Aug. 3, 2006

(54) In situ formed halo region in a transistor device

(76) Inventors: Thorsten Kammler, Ottendorf-Okrilla (DE); Andy Wei, Dresden (DE); Helmut Bierstedt, Dresden (DE)

Correspondence Address: WILLIAMS, MORGAN & AMERSON, 10333 RICHMOND, SUITE 1100, HOUSTON, TX, 77042, US

(21) Appl. No.: 11/203,848

(22) Filed: Aug. 15, 2005

(30) Foreign Application Priority Data
Jan. 31, 2005 (DE) 10 2005 004 411.5

(51) Int. Cl. H01L 21/20; H01L 21/36

(52) U.S. Cl. 438/481

(57) ABSTRACT

By performing a sequence of selective epitaxial growth processes with at least two different species, or by introducing a first dopant species prior to the epitaxial growth of a drain and source region, a halo region may be formed in a highly efficient manner, while at the same time the degree of lattice damage in the epitaxially grown semiconductor region is maintained at a low level.

### BACKGROUND OF THE INVENTION

1. Field of the Invention

Generally, the present invention relates to the formation of integrated circuits, and, more particularly, to the formation of semiconductor regions including enhanced dopant profiles formed by means of halo regions.

2. Description of the Related Art

The fabrication of integrated circuits requires the formation of a large number of circuit elements on a given chip area according to a specified circuit layout. For this purpose, substantially crystalline semiconductor regions with or without additional dopant materials are defined at specified substrate locations to act as “active” regions, that is, to act, at least temporarily, as conductive areas. Generally, a plurality of process technologies are currently practiced, wherein, for complex circuitry, such as microprocessors, storage chips and the like, MOS technology is currently one of the most promising approaches, due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A transistor, irrespective of whether an N-channel transistor or a P-channel transistor or any other transistor architecture is considered, comprises so-called PN junctions that are formed by an interface of highly doped regions, such as drain and source regions, with a slightly doped or non-doped region, such as a channel region, disposed adjacent to the highly doped regions.

In the case of a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length, and associated therewith the reduction of channel resistivity and increase of gate resistivity, renders the channel length a dominant design criterion for accomplishing an increase in the operating speed of the integrated circuits.

The continuing shrinkage of the transistor dimensions, however, entails a plurality of issues associated therewith that have to be addressed so as to not unduly offset the advantages obtained by steadily decreasing the dimensions of transistors. One major problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control, as reducing the channel length also requires reducing the depth of the drain and source regions with respect to the interface formed by the gate insulation layer and the channel region, thereby calling for sophisticated implantation techniques. According to other approaches, epitaxially grown regions are formed with a specified offset to the gate electrode, which are referred to as elevated or raised drain and source regions, to provide increased conductivity of the raised drain and source regions, while at the same time maintaining a shallow PN junction with respect to the gate insulation layer.

Furthermore, since the continuous size reduction of the critical dimensions, e.g., the gate length of the transistors, necessitates the adaptation and possibly the new development of highly complex process techniques concerning the above-identified process steps, it has been proposed to also enhance device performance of the transistor elements by increasing the charge carrier mobility, for instance, in the channel region for a given channel length, thereby offering the potential for achieving a performance improvement that is comparable with the advance to a future technology node of down-sized devices while avoiding many of the above process adaptations associated with device scaling.

In principle, at least two mechanisms may be used, in combination or separately, to increase the mobility of the charge carriers in the channel region. First, in field effect transistors, the dopant concentration within the channel region may be reduced, thereby reducing scattering events for the charge carriers and thus increasing the conductivity. However, reducing the dopant concentration in the channel region significantly affects the threshold voltage of the transistor device, thereby presently making a reduction of the dopant concentration a less attractive approach unless other mechanisms are developed to adjust a desired threshold voltage. Second, the lattice structure in respective semiconductor regions, such as the channel region, may be dilated/stretched, for instance by creating tensile or compressive strain therein, which results in a modified mobility for electrons and holes, respectively. For example, creating uniaxial tensile strain in the channel region of a field effect transistor with respect to the current flow direction increases the mobility of electrons, wherein, depending on the magnitude and direction of the tensile strain, an increase in mobility of up to 120% or more may be obtained, which, in turn, may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor, which may enable the fabrication of fast powerful semiconductor devices without requiring expensive semiconductor materials and manufacturing techniques.

Consequently, it has been proposed to introduce, for instance, a silicon/germanium layer in or below the channel region to create tensile or compressive stress that may result in a corresponding strain.

With reference to FIGS. 1a-1c, a typical conventional application for epitaxially grown silicon/germanium regions in P-channel transistors will now be discussed in more detail to illustrate the problems involved in the conventional approach.

FIG. 1a schematically shows a cross-sectional view of a P-channel transistor 100 including a substrate 101, such as a silicon-based crystalline bulk substrate, a silicon-on-insulator (SOI) substrate having formed thereon a crystalline silicon layer, and the like. The substrate 101 comprises a channel region 102, which may be lightly N-doped, which is separated from a gate electrode 104 by a thin gate insulation layer 103. Typically, the gate electrode 104 may substantially be comprised of polysilicon, whereas the gate insulation layer 103 may be formed of silicon dioxide and/or silicon nitride and/or silicon oxynitride or any other appropriate dielectric material. On sidewalls of the gate electrode 104 are formed spacer elements 106, which are separated from the gate electrode 104 by corresponding liners 105. For example, the liner 105 may be comprised of silicon dioxide, while the spacer elements may be formed of silicon nitride. However, other configurations, such as silicon nitride liners and silicon dioxide spacers are also compatible with a typical transistor architecture. Moreover, a cap layer 107, for instance comprised of silicon nitride, covers the gate electrode 104 so that, in combination with the spacer elements 106, the gate electrode 104 is entirely embedded into a dielectric material.

A typical process flow for forming the P-channel transistor 100 as shown in FIG. 1a may comprise the following processes. After the formation of any isolation structures (not shown), a corresponding vertical dopant profile within the substrate 101 may be defined by accordingly designed implantation cycles. Thereafter, corresponding material layers for the gate insulation layer 103 and the gate electrode 104 may be formed by appropriate techniques, such as thermal or wet chemical oxidation and/or deposition for the dielectric layer of the gate insulation 103, while low pressure chemical vapor deposition (LPCVD) methods may be used in depositing polysilicon for the gate electrode 104. Moreover, further material layers, such as material for the cap layer 107, which may act as a portion of an anti-reflective coating (ARC), may also be deposited in accordance with well-established process recipes. The resulting layer stack may then be patterned by advanced photolithography and etch techniques, followed by the formation of the liner 105, for instance by thermal oxidation, and a subsequent deposition of spacer layer material, which is then patterned by well-established anisotropic etch techniques, thereby resulting in the formation of the sidewall spacers 106.

As previously explained, uniaxial compressive strain within the channel region 102 in the current flow direction may significantly enhance the mobility of holes, thereby enhancing the overall performance of the P-channel transistor 100. In order to provide the desired compressive strain, the transistor element 100 is subjected to an anisotropic etch process 108 to form appropriate recesses, indicated by dashed lines and the reference number 109, within the substrate 101 adjacent to the sidewall spacers 106. After the formation of the recesses 109, any clean processes may be performed to remove contaminants and etch by-products from within the recesses 109, thereby allowing a highly selective epitaxial growth process generating a pseudomorphic layer of silicon/germanium at moderately low temperatures in the range of approximately 700-900° C. During this epitaxial growth process, a P-type dopant, such as boron, is added to the deposition atmosphere to not only provide a silicon/germanium material within the recesses 109 but also a required degree of doping, thereby forming drain and source regions 110 for the transistor 100.

FIG. 1b schematically shows the transistor 100 after the completion of the process sequence described above. Thus, the transistor element 100 comprises silicon/germanium containing source and drain regions 110, which are highly P-doped, for instance by boron, to impart the desired conductivity to the regions 110. Moreover, due to the slight lattice mismatch between the crystalline silicon/germanium material and the surrounding silicon substrate 101 and the channel region 102, a corresponding compressive strain is generated in the channel region 102 by the compressively stressed drain and source regions 110, thereby providing the desired increase of the hole mobility therein. However, boron exhibits a high diffusivity during any elevated temperatures encountered during the further processing of the device 100 and even during the selective epitaxial growth process for forming the regions 110. Consequently, the dopant profile forming the PN junction between the substrate 101 and in particular the channel region 102 and the boron doped source and drain regions 110 may be smeared out and may therefore adversely affect the controllability of short channel effects in the channel region 102 during the operation of the transistor element 100. In order to reduce the effects of undue boron diffusion on the transistor performance and to control the short channel effects, a so-called halo region is formed around the source and drain regions 110 by introducing a dopant material of inverse doping characteristics, such as arsenic, to thereby “reinforce” the PN junction between the boron doped source and drain regions 110 and the N-doped channel region 102 and the substrate 101.

FIG. 1c schematically shows the transistor device 100 during a tilted halo implantation 113 for introducing an N-type dopant, such as arsenic, into the substrate 101, thereby forming halo regions 111 adjacent to the drain and source regions 110. However, during the halo implantation 113, a plurality of crystal defects in the form of dislocations, point defects, stacking faults and (prismatic) dislocation rings, indicated as 112, are generated within the stressed source and drain regions 110, thereby resulting in a certain degree of undesired relaxation of the compressive stress in these regions, which also causes a decrease of strain induced in the channel region 102. Hence, the effect of hole mobility enhancement within the channel region 102 is significantly lessened. As a consequence, although the problem of adverse boron diffusion and hence deteriorated channel controllability may be addressed, at least to a certain degree, by the above-described conventional approach, a reduced transistor performance with respect to operating speeds and current drive capability may nevertheless result owing to a reduced strain formation in the channel region 102.

In view of the above-described situation, there exists a need for an enhanced technique that provides increased flexibility in creating doped regions on the basis of selective epitaxy processes while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is directed to a technique that enables the formation of selectively epitaxially grown semiconductor regions, wherein at least one dopant species is introduced during the epitaxial growth process and wherein an interface in a semiconductor material, formed by at least two different dopant species incorporated in the semiconductor material, is provided substantially without crystalline defects, such as dislocations, point defects, stacking faults and (prismatic) dislocation rings.

According to one illustrative embodiment of the present invention, a method comprises forming a first crystalline semiconductor region by a first selective epitaxial growth process, wherein the first crystalline semiconductor region comprises a first dopant species. Furthermore, a second crystalline semiconductor region is formed adjacent to the first crystalline semiconductor region by a second epitaxial growth process, wherein the second crystalline semiconductor region comprises a second dopant species that is different from the first dopant species.

In accordance with still another illustrative embodiment of the present invention, a method comprises forming a recess in a semiconductor layer adjacent to a gate electrode structure formed above the semiconductor layer and introducing a first dopant species into the semiconductor layer via the recess. Moreover, the method comprises forming a crystalline semiconductor region within the recess by a selective epitaxial growth process, wherein the crystalline semiconductor region comprises a second dopant species that differs from the first dopant species.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a conventional P-channel transistor receiving a pre-doped silicon/germanium source and drain region during various manufacturing stages in accordance with a conventional process flow; and

FIGS. 2a-2d schematically show cross-sectional views of a semiconductor circuit element during various manufacturing stages in forming epitaxially grown semiconductor regions to provide at least two different dopant species within or within and adjacent to the epitaxially grown semiconductor region in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

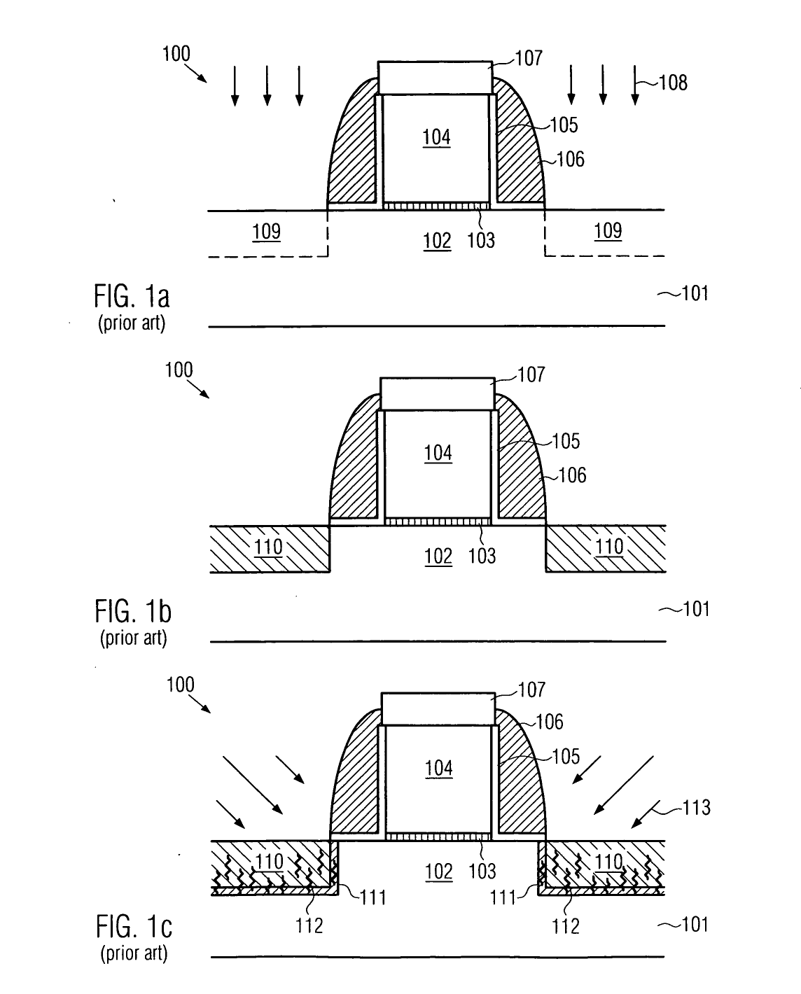

In general, the present invention relates to the formation of semiconductor regions by a selective epitaxial growth process, wherein at least one dopant species is introduced into the epitaxially grown semiconductor region by adding a precursor containing the dopant species into the deposition atmosphere. As previously pointed out, in many applications, it is desirable to also provide a second dopant species within the semiconductor region or adjacent thereto to form a well-defined interface between the first dopant species and the second dopant species. In some particular embodiments, the interface may represent a PN junction, wherein the location of the interface, as well as the dopant concentrations and gradients at and in the vicinity of the interface, significantly affect the overall electrical performance as well as the long-term diffusion characteristics of the semiconductor device under consideration. For the purpose of forming a well-defined interface of two different dopant species, such as dopant species of different types of conductivity, the present invention provides a technique that enables the formation of the interface by introducing at least one of the dopant species during the selective epitaxial growth process while the creation of undue lattice defects is reduced, contrary to, for instance, the conventional process technique described with reference to FIGS. 1a-1c, thereby providing the potential for appropriately designing the characteristics of the interface without undue adverse effects of crystalline defects such as dislocations and glides.

Thus, the present invention is particularly advantageous in combination with epitaxially grown semiconductor regions having a slight lattice mismatch to the surrounding semiconductor material to provide specific advantageous characteristics, such as increased carrier mobility, and the like. In some illustrative embodiments, an epitaxially grown semiconductor region having a specified lattice mismatch to the neighboring substrate material may be used to create a specified strain in a channel region of a field effect transistor, wherein the strain transfer mechanism from the epitaxially grown semiconductor region into the channel region is significantly enhanced compared to conventional approaches due to the reduction or even avoidance of dislocation and glides, while nevertheless a pronounced PN junction may be provided.

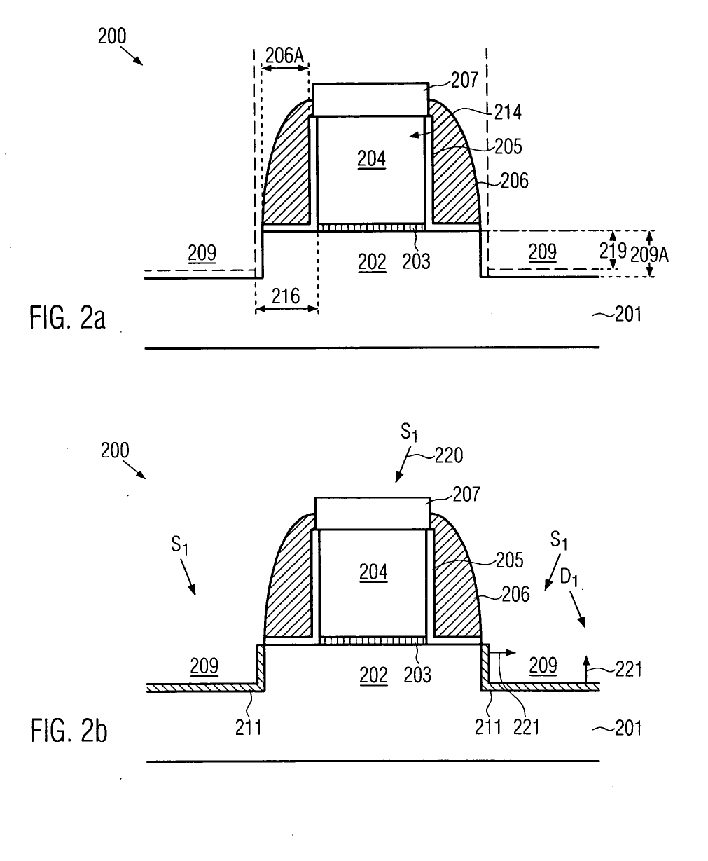

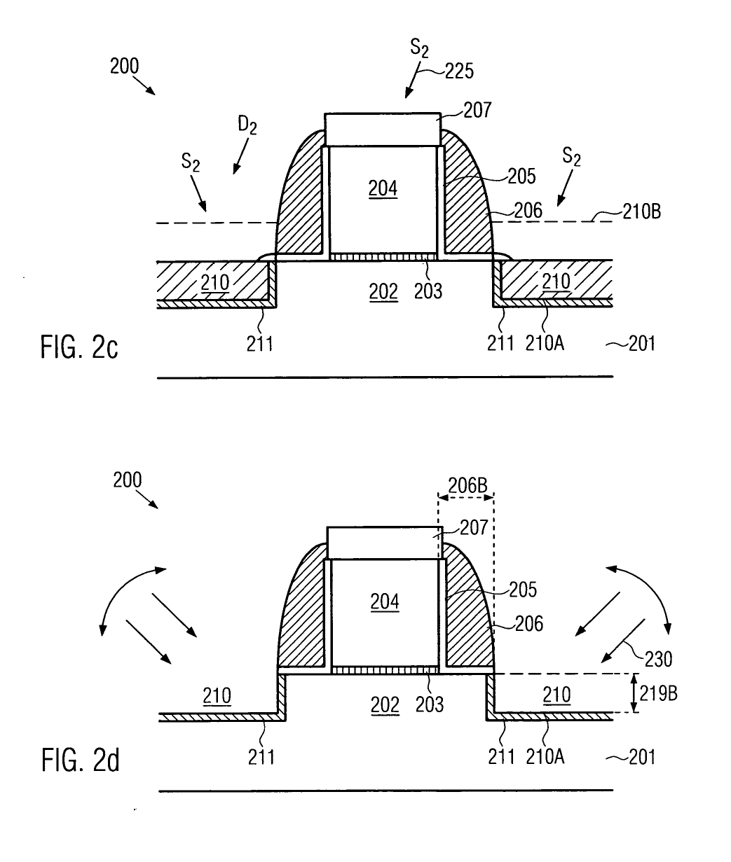

Although the present invention is highly advantageous in combination with transistor elements receiving an epitaxially grown drain and source region, or at least a portion thereof, wherein the epitaxially grown regions are stressed due to a lattice mismatch to the surrounding semiconductor material, such as, for example, a P-channel transistor receiving a silicon/germanium drain/source region, the present invention also offers high flexibility in designing any crystalline semiconductor region requiring a well-defined interface or PN junction, wherein the dopant concentration and gradient, as well as the type of dopant material and the type of semiconductor material, may readily be selected in accordance with process and device requirements. It is, therefore, to be appreciated that, although many of the illustrative embodiments described with reference to FIGS. 2a-2d refer to a transistor element receiving a strained drain and source region, the present invention should not be restricted to these illustrative embodiments, unless such restrictions are explicitly set forth in the appended claims.

FIG. 2a schematically shows a cross-sectional view of a semiconductor device 200, which may represent any circuit element requiring a crystalline semiconductor region of specified characteristics and including a well-defined interface of two different dopant species, such as a PN junction in a transistor element, diode and the like. In one particular embodiment, the semiconductor device 200 represents a field effect transistor wherein drain and source regions are formed, at least partially, of an epitaxially grown semiconductor region. The semiconductor device 200 may comprise a substrate 201, which may represent any appropriate substrate for forming thereon and therein the respective components of the device 200. In illustrative embodiments, the substrate 201 may represent a silicon bulk substrate or a silicon-on-insulator (SOI) substrate having formed thereon a crystalline silicon layer. In other embodiments, the substrate 201 may represent any semiconductor bulk substrate or insulating substrate having formed thereon an appropriate semiconductor layer. For instance, the substrate 201 may comprise a semiconductor layer of silicon having locally different surface orientations, or the substrate 201 may represent a silicon/germanium semiconductor layer, a germanium semiconductor layer, or any other appropriate composite semiconductor material. When representing a field effect transistor, the device 200 may comprise a channel region 202 above which is formed a gate electrode structure 214 including a gate electrode 204 that is separated and insulated from the channel region 202 by a gate insulation layer 203. The gate electrode 204 may be comprised of doped polysilicon or any other appropriate material. In some transistor architectures, the gate electrode 204 may not be provided in this stage of manufacture but instead may be represented by a place holder structure, which may be replaced by a highly conductive material in a later stage of manufacture. The gate electrode structure 214 may have formed on sidewalls thereof spacer elements 206, which may include a liner 205, wherein the spacer 206 and the liner 205 may be formed of dielectric materials of high etch selectivity with respect to a specified anisotropic etch recipe used for forming the spacers 206. For instance, the spacer 206 may be comprised of silicon nitride while the liner 205 may be formed of silicon dioxide and vice versa. Moreover, the gate electrode 204 is covered by a cap layer 207, for instance comprised of silicon nitride, silicon oxynitride, and the like, while in embodiments in which the gate electrode structure 214 includes a dielectric place holder instead of the gate electrode 204, the cap layer 207 may be omitted.

The semiconductor device 200 as shown in FIG. 2a may be formed in accordance with the following processes. First, the substrate 201 may be obtained from an appropriate manufacturer or may be formed in accordance with well-established processes, such as global epitaxial growth and the like. Thereafter, isolation structures (not shown) may be formed by well-known techniques, followed by implantation cycles to create a desired vertical dopant profile within the substrate 201 and in particular within the channel region 202. Thereafter, the gate electrode structure 214 may be formed by well-established and advanced photolithography and etch techniques, wherein the cap layer 207 may be formed prior to the patterning of the gate electrode 204. Thereafter, the sidewall spacers 206 may be formed in accordance with well-established spacer techniques, wherein a width 206a of the spacer 206 is adjusted on the basis of a target distance 216 of an interface between two different dopant species to be formed within the substrate 201. For instance, the target distance 216 may represent the target distance of a PN junction with respect to the sidewall of the gate electrode 204. In one particular embodiment, the device 200 may represent a P-type transistor, in which the channel region 202 and the substrate 201, at least in the vicinity of the gate electrode structure 214, is lightly N-doped. Hereby, the target distance 216 may represent the lateral position of a PN junction between the channel region 202 and a drain and source region to be formed adjacent to the gate electrode structure 214. Consequently, the width 206a of the spacer element 206, including the width or thickness of the liner 205, may be selected to take into consideration the thickness of a semiconductor material to be deposited in a subsequent selective epitaxial growth process including a first dopant to laterally position an interface between a first dopant and a second dopant substantially at the target distance 216.

Similarly, a target depth 219 may be selected in advance, which may then be used in controlling a subsequent anisotropic etch process to form recesses 209 adjacent to the gate electrode structure 214 and the spacers 206. A corresponding selective anisotropic etch process for removing material of the crystalline substrate 201 may be performed on the basis of well-established process recipes, wherein material removal of the spacers 206 and the cap layer 207 is significantly less due to a moderately high etch selectivity. Moreover, during this anisotropic etch process, the etch time may be controlled for otherwise fixed process parameters to achieve a depth 209a that is selected on the basis of the target depth 219, thereby also taking into consideration a desired thickness of semiconductor material including the first dopant species, while the target depth 219 substantially determines a target position of the interface between the first and second dopant species. In some illustrative embodiments, in which the device 200 may represent an advanced P-channel transistor having a gate length, that is, the horizontal dimension of the gate electrode 204 in FIG. 2a, of less than approximately 100 nm or even less than approximately 50 nm, the difference between the target depth 219 and the actual depth 209a of the recess 209 may range from approximately 5-20 nm. It should be appreciated, however, that in other transistor architectures, the corresponding difference between the target depth 219 and the recess depth 209a may be selected in accordance with process and device requirements. Similarly, the difference between the lateral target distance 216 and the spacer width 206a may be adjusted in accordance with design requirements and may range from approximately 5-20 nm for an advanced P-channel transistor. It should be appreciated that, by individually adjusting the spacer width 206a and the recess depth 209a, the lateral and vertical position of a dopant interface, e.g., a PN junction, may substantially be decoupled from each other. Thus, in a transistor design in which a “reinforced” PN junction is to be formed, the individual adjustment of the spacer width 206a and the depth 209a enable a certain degree of flexibility in designing the corresponding “halo” region during the subsequent selective epitaxial growth processes, as will be described with reference to FIGS. 2b and 2c.

FIG. 2b schematically shows the semiconductor device 200 when subjected to a first selective epitaxial growth process 220. During the growth process 220, a first semiconductor material, indicated as S1, is selectively deposited within the recesses 209, whereas any deposition of the first semiconductor material S1 on dielectric portions, such as the spacers 206 and the cap layer 207, is substantially prevented. Moreover, a precursor gas is added to the atmosphere of the growth process 220 containing a specified first dopant species, indicated as D1, to form a first epitaxially grown semiconductor region 211 within the recesses 209, wherein the first semiconductor region 211 comprises the first dopant species D1 in a concentration and distribution along the direction of growth 221 as is determined by process parameters of the growth process 220. That is, in some illustrative embodiments, a precursor gas containing the first dopant species D1 may be added to the deposition atmosphere in a substantially continuous and constant fashion starting from a specified time point with respect to the beginning of the deposition process, thereby creating a substantially constant concentration of the first dopant species within a portion of the region 211 that is deposited after the initiation of the precursor gas supply to the deposition atmosphere. In other embodiments, the supply of the first dopant species may be varied during at least a specified time period of the deposition 220 to obtain a varied dopant concentration along the growth direction 221 of the first semiconductor region 211. For instance, after the initiation of the growth process 220, the supply of a dopant-containing precursor gas may be increased, continuously or step-wise, to form a gradually varying dopant concentration along the direction of growth 221 of the region 211.

It should be appreciated that, by correspondingly varying the precursor gas concentration within the deposition atmosphere, any desired concentration variation may be created to provide the desired characteristics at an interface between the first semiconductor region 211 and a second semiconductor region to be formed adjacent to the first region 211. In some illustrative embodiments, the first semiconductor region 211 may be comprised of a material having a similar but nevertheless slightly different lattice structure compared to the material of the neighboring substrate 201 such that the semiconductor material 211 may be considered as a stressed material having the lattice structure of the substrate material 201. For instance, the semiconductor region 211 may be comprised of a mixture of silicon/germanium, or silicon/carbon, when the substrate material 201 comprises silicon, germanium or any mixture thereof. Accordingly, by appropriately selecting the ratio of silicon and germanium or silicon and carbon during the growth process 220, a desired degree of lattice mismatch and thus of stress created in the region 211 may be selected. In one particular embodiment, the device 200 represents a P-channel transistor, in which the first semiconductor region 211 is deposited on a silicon-based substrate material acting as a crystal template and comprises a silicon/germanium compound, wherein an N-type dopant material, such as arsenic, is incorporated into the region 211, in a gradual or step-wise fashion, with a desired concentration to form a halo region enclosing source and drain regions still to be formed. The characteristics of the halo region 211 may be adjusted by the dopant profile within the region 211, that is, by the dopant concentration and its local variation along the direction of growth 221, and by the thickness of the region 211, which is determined by the process parameters of the growth process 220.

It should be appreciated that, prior to the growth process 220, any dry and wet clean processes are performed to remove or at least significantly reduce any contaminants at surface portions of the recesses 209 to enable a reliable selective deposition of the first semiconductor material S1 at moderately low deposition temperatures. For instance, depending on the efficiency of the preceding clean processes and depending on the capability of precisely controlling the deposition atmosphere of the process 220, a selective deposition may be achieved at temperatures as low as approximately 650° C., whereas lower temperatures may be achievable in the near future, depending on advances in the design of appropriate deposition reactors, the development of new clean recipes and the like.

FIG. 2c schematically shows the device 200 during a second epitaxial growth process 225 for selectively depositing a second semiconductor material, indicated as S2, in the presence, at least temporarily, of a second dopant species, indicated as D2, thereby forming a second crystalline semiconductor region 210 adjacent to the first region 211. In one particular embodiment, the first growth process 220 and the second growth process 225 may be performed as in situ sequence, wherein at least the supply of the second dopant material D2 is initiated during the second step 225 to form a desired interface 210a with required characteristics with respect to dopant gradient, overall concentration and lateral and vertical position. Thus, in some embodiments, substantially the same semiconductor material may be deposited during the second process 225 as in the first process 220, while additionally or alternatively the second dopant D2 is supplied during the second process 225. As previously explained with reference to the region 211, also during the second epitaxial growth process 225, the supply of the second dopant species D2 may be controlled to obtain a specified dopant concentration and a desired variation especially in the vicinity of the interface 210a. Hence, depending on device requirements, a moderately sharp or graded transition from the region 211 to the region 210, with respect to the type of dopant and possibly with respect to the type of semiconductor material, may be obtained in accordance with process parameters, such as precursor gas concentration in the deposition atmosphere of the steps 220 and 225.

For the particular embodiment described above, when the device 200 represents the P-channel transistor, the second semiconductor material S2, for instance comprised of silicon/germanium, may be deposited in the presence of a P-type dopant material, such as boron, to form a PN junction at the interface 210a, the characteristics of which may be adjusted by controlling the supply of the first and second dopant species during the first and second growth processes 220 and 225. Consequently, the region 211 may represent a halo region, which stabilizes the characteristics of the PN junction 210a with respect to diffusion, even if a highly diffusive dopant material, such as boron, is incorporated into the region 210. Moreover, contrary to the conventional approach described with reference to FIGS. 1a-1c, the regions 210 and 211 are formed by epitaxy to define the interface 210a, for instance in the form of a PN junction, without requiring the implantation of a dopant species. Consequently, implantation-induced lattice damage may substantially be avoided within the regions 210 and 211 so that the lattice structure as provided by the epitaxial growth processes 220 and 225 is substantially maintained. Therefore, if the semiconductor regions 211 and/or 210 are provided with a material composition that results in the formation of one or two stressed areas due to a lattice mismatch to the neighboring crystalline material, the intrinsic stress is substantially maintained and may therefore induce a corresponding strain in the channel region 202 in a highly efficient manner. If, for example, the illustrative embodiment of a P-channel transistor is considered, the second semiconductor region 210 may be provided with a desired high boron concentration within a silicon/germanium composition, while the region 211, acting as a halo region, provides the required N-type conductivity, for instance in the form of arsenic, while any undue stress relaxation in the regions 210 and 211 is substantially prevented. In other embodiments, any other appropriate material composition may be formed by the first and second growth processes 220 and 225, such as silicon/carbon, or any other binary, ternary or even higher complex semiconductor compositions as are required for providing the desired stress characteristics and/or charge carrier mobility properties within the regions 210 and 211. For instance, the regions 211 and/or 210 do not necessarily need to be deposited to become stressed regions. In this case, well-defined PN junctions with well-defined dopant concentrations may be formed from a material that is substantially identical to the substrate material, whereas, due to the epitaxial growth nature of the processes 220 and 225, corresponding anneal cycles for activating dopants and curing lattice damage may be obsolete. Consequently, the overall vertical and lateral dopant profile within the channel region 202 and the regions 210 and 211 may be defined in a more precise fashion, whereas especially a retrograde vertical profile in the channel region 202 may substantially be maintained due to the lack of any high temperature anneal cycles that may be required in transistor devices receiving source and drain regions by ion implantation.

In other embodiments, a further epitaxial growth process may be performed to increase the height of the regions 210 to a specified value, as is indicated by the dashed lines 210b, as is frequently required in transistor architectures having extremely shallow PN junctions, wherein the elevated or raised drain and source regions provide the desired low contact resistivity.

In the embodiments described above, a high degree of flexibility in locating the interface 210a is provided, while at the same time the characteristics of the interface 210a and the areas in the vicinity of the interface 210a may be designed by correspondingly controlling the growth processes 220 and 225. For instance, the thickness of the region 211 may be controlled by correspondingly adjusting the spacer widths 206a and the depth of the recess 209a (FIG. 2a) in combination with process parameters of the growth processes 220 and 225, such as deposition time for a given deposition rate. In some embodiments, it may be desirable to provide even more flexibility in designing the region 211, especially when the region 211 acts as a halo region, which then significantly affects the characteristics of the resulting PN junction and thus substantially influences the overall performance of the resulting transistor element.

FIG. 2d schematically shows the semiconductor device 200 in a manufacturing stage that substantially corresponds to the manufacturing stage as shown in FIG. 2a, wherein the device 200 is subjected to an ion implantation 230 or a plasma treatment to introduce a desired amount of the first dopant species into surface areas of the recess 209. As a result of the ion implantation 230 or plasma treatment, the first semiconductor region 211 is formed, wherein its dimensions and characteristics with respect to dopant concentration and profile are determined by the respective spacer width 206b and the recess depth 219b, which may differ from the respective values as described with reference to FIG. 2a. For instance, the spacer width 206b and the depth 219b may substantially coincide with the respective target values 216 and 219. Moreover, the configuration of the resulting doped semiconductor region 211 may significantly be determined by the process parameters of the ion implantation 230 or plasma treatment. For instance, by performing a tilted implantation, wherein the tilt angle may be varied continuously or step-wise, a highly complex dopant profile for the halo region 211 may be achieved. Since the required penetration depth of the dopant species during the implantation 230 or plasma treatment is relatively low, the implantation energies required are also relatively low and therefore corresponding implantation-induced damage may be kept at a very low level.

Moreover, in applications in which a substantially asymmetric design of the transistor architecture with respect to the halo region and/or a corresponding PN junction is required, a corresponding asymmetric ion implantation 230 may be performed. For instance, one or more dopant species may be introduced by tilted implantations in a highly asymmetric fashion, whereas the bulk of the drain and source materials including the high dopant concentration may then be formed by a subsequent selective epitaxial growth process. A corresponding process flow may be advantageous when an asymmetric transistor configuration is to be combined with an efficient strain-inducing mechanism, since the overall lattice damage is kept at a low level.

In some embodiments, an additional anneal cycle at moderately low temperatures and short duration may be performed to reduce even the low number of crystal defects by substantially re-crystallizing any implantation-induced damage. In other embodiments, dry pre-clean processes, required prior to the selective epitaxial growth process, may be performed to establish a plasma ambient, in which a specified dopant species is driven into the exposed surfaces of the recess 209. Also, in this case, corresponding process parameters of the plasma treatment may be controlled to deposit a desired amount of, for instance, arsenic at the surface layer of the recesses 209. After completion of the cleaning processes, performed with or without a plasma treatment, the deposition of further semiconductor material may be performed substantially in the same fashion as is also described with reference to FIG. 2c to thereby form the region 210 including a specified intrinsic stress and/or a specified further dopant species.

As a result, the present invention provides an improved technique that allows the formation of doped semiconductor regions including at least two different types of dopant species to define the characteristics of an interface between the two dopant species in a highly precise manner, while lattice defects within the doped semiconductor region are kept at a moderately low level. To this end, a sequence of epitaxial growth processes may be performed to provide at least two dopant species in a highly precise fashion substantially without lattice damage, as is the case in conventional halo implantations through a doped epitaxially grown semiconductor region. Consequently, enhanced flexibility in designing, for instance PN junctions, is provided in combination with improved device performance owing to a reduced number of lattice defects. In particular embodiments, the epitaxially grown semiconductor region may represent a stressed region, which may transfer the stress to a channel region in a more efficient manner due to the reduced number of lattice defects and thus a significantly reduced relaxation mechanism during the formation of halo regions. Moreover, in some embodiments, highly efficient implantation or plasma treatment processes may be combined with a selective epitaxial growth process to form, for instance, halo regions and/or PN junctions in a highly flexible fashion, for instance in an asymmetric configuration, while nevertheless maintaining implantation-induced lattice damage at a low level. Thus, when providing the epitaxially grown semiconductor region with intrinsic stress, a corresponding strain in the channel region of the transistor may be created in a highly efficient manner.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first crystalline semiconductor region by a first selective epitaxial growth process, said first crystalline semiconductor region comprising a first dopant species; and
forming a second crystalline semiconductor region adjacent to said first crystalline semiconductor region by a second epitaxial growth process, said second crystalline semiconductor region comprising a second dopant species other than said first dopant species.

2. The method of claim 1, wherein said first and second epitaxial growth processes are performed sequentially in situ as a common growth process.

3. The method of claim 1, further comprising providing a crystalline template material at least for said first epitaxial growth process, wherein said crystalline template material has a different lattice spacing compared with said first crystalline semiconductor region.

4. The method of claim 1, wherein said first and second crystalline semiconductor regions are formed from substantially the same material.

5. The method of claim 1, wherein said first crystalline semiconductor region and said second crystalline semiconductor region form a PN junction.

6. The method of claim 1, further comprising forming a gate electrode structure prior to forming said first and second semiconductor regions.

7. The method of claim 6, further comprising covering said gate electrode structure with dielectric material to substantially prevent semiconductor material from depositing on said covered gate electrode structure.

8. The method of claim 7, wherein covering said gate electrode structure comprises forming sidewall spacers at sidewalls of said gate electrode structure, said sidewall spacers having a width so as to define a minimum lateral distance of said first crystalline semiconductor region to said gate electrode structure.

9. The method of claim 8, further comprising forming a recess, adjacent to said sidewall spacers, in a semiconductor layer above which said gate electrode is formed.

10. The method of claim 9, further comprising defining a target thickness of said first crystalline semiconductor region and a target depth of an interface between said first and second semiconductor regions and forming said recess on the basis of said target thickness and said target depth.

11. The method of claim 1, wherein said first dopant species comprises an N-type dopant species.

12. The method of claim 1, wherein said second dopant species comprises a P-type dopant species.

13. The method of claim 1, wherein forming said first crystalline semiconductor region comprises controlling an introduction of a precursor containing said first dopant species to form a substantially constant concentration of said first dopant species within said first crystalline semiconductor region.

14. The method of claim 1, wherein forming said first crystalline semiconductor region comprises controlling an introduction of a precursor containing said first dopant species to form a varying concentration of said first dopant species within said first crystalline semiconductor region.

15. The method of claim 1, wherein forming said second crystalline semiconductor region comprises controlling an introduction of a precursor containing said second dopant species to form a substantially constant concentration of said second dopant species within said second crystalline semiconductor region.

16. The method of claim 1, wherein forming said second crystalline semiconductor region comprises controlling an introduction of a precursor containing said second dopant species to form a varying concentration of said second dopant species within said second crystalline semiconductor region.

17. The method of claim 1, wherein forming said first crystalline semiconductor region and forming said second crystalline semiconductor region defines a junction region comprising said first and second dopant species.

18. A method, comprising:
forming a recess in a semiconductor layer adjacent to a gate electrode structure formed above said semiconductor layer;
introducing a first dopant species into said semiconductor layer via said recess; and
forming a crystalline semiconductor region within said recess by a selective epitaxial growth process, said crystalline semiconductor region comprising a second dopant species other than said first dopant species.

19. The method of claim 18, wherein said first dopant species is introduced by one of a plasma treatment and an ion implantation.

20. The method of claim 18, wherein said first dopant species is introduced by a selective epitaxial growth process on the basis of a precursor material containing said first dopant species.

21. The method of claim 18, wherein said first dopant species and said second dopant species are of inverse conductivity type.

22. The method of claim 18, wherein said crystalline semiconductor region is formed with a specified intrinsic stress.

23. The method of claim 18, wherein said first dopant species is introduced in an asymmetric manner with respect to said gate electrode structure.

24. The method of claim 18, wherein said first and second dopant species define a junction region in said semiconductor region.
